(19) United States
(12) Patent Application Publication
(10) Pub. No.: US 2015/0340124 A1
(43) Pub. Date: Nov. 26, 2015

(54) PRINTED CIRCUIT BOARD AND CARD READER

(71) Applicant: NIDEC SANKYO CORPORATION, Suwa-gun (JP)

(72) Inventors: Kazuhiro GOMI, Suwa-gun (JP); Toshiro SHIOMI, Suwa-gun (JP)

(21) Appl. No.: 14/721,475

(22) Filed: May 26, 2015

(30) Foreign Application Priority Data
May 26, 2014 (JP) 2014-107702

(51) Int. Cl. H01B 5/04; H05K 7/14; G06K 7/01; H05K 1/02

(52) U.S. Cl. CPC H01B 5/04; H05K 1/028; H05K 7/1427; G06K 7/01

(57) ABSTRACT

A destruction detection pattern for use on a printed circuit board formed in a plate shape or a film shape may include a conductor wound in a spiral shape. A width of the conductor may be constant. Within an imaginary square overlaying the destruction detection pattern, the imaginary square having a side length that is 12 times the width of the conductor, and wherein a first direction is parallel to a first side of the imaginary square and a second direction parallel to a second side of the imaginary square that is perpendicular to the first side, the destruction detection pattern may include a first pattern part, a second pattern part, a third pattern part and a fourth pattern part. The destruction detection pattern may be structured to detect its own disconnection or its own short circuit.

### CROSS REFERENCE TO RELATED APPLICATION

The present application claims priority under 35 U.S.C. §119 to Japanese Application No. 2014-107702 filed May 26, 2014, the entire content of which is incorporated herein by reference.

### FIELD OF THE INVENTION

At least an embodiment of the present invention may relate to a printed circuit board which is formed in a plate shape or a film shape. Further, at least an embodiment of the present invention may relate to a card reader including the printed circuit board.

### BACKGROUND

Conventionally, a destruction detection pattern plate for detecting illegal access to an electronic component requiring a security property from the outside has been known (see, for example, Japanese Patent Laid-Open No. 2009-140279). The destruction detection pattern plate described in the Patent Literature includes an insulative base member made of glass epoxy material and a wiring pattern formed on a surface of the base member. The wiring pattern is structured of one power supply line and ground lines disposed on both sides with respect to the power supply line. Further, the wiring pattern is structured so that a straight-shaped power supply line and straight-shaped ground lines are wound around in a substantially rectangular spiral shape to form a spiral as a base unit and so that a plurality of the spirals is adjacently disposed to each other. A plurality of the spirals is formed in a substantially same shape and the wiring pattern is formed by disposing a plurality of the spirals so that outward forms of the spirals in a substantially rectangular shape are contacted with each other.

In the destruction detection pattern plate described in the Patent Literature, a spiral is formed by winding a straight-shaped power supply line and ground line to form a substantially rectangular spiral shape and the wiring pattern is formed by disposing a plurality of the spirals so that outward forms of a plurality of the spirals are contacted with each other. Therefore, in a case that a space between the power supply lines structuring the wiring pattern is not narrowed, when the destruction detection pattern plate is cut by a cutter or the like, the power supply line is hard to be cut and, as a result, it is difficult to secure the security property.

### SUMMARY

In view of the problem described above, at least an embodiment of the present invention may advantageously provide a printed circuit board which is formed with a destruction detection pattern even when a space between conductor patterns structuring the destruction detection pattern is made relatively wide, a security property of the device to which the printed circuit board is attached can be secured. Further, at least an embodiment of the present invention may advantageously provide a card reader including the printed circuit board.

According to at least an embodiment of the present invention, there may be provided a printed circuit board formed in a plate shape or a film shape, including a destruction detection pattern for detecting its own disconnection and/or its own short circuit. The destruction detection pattern is formed so that a conductor pattern structured by a combination of a straight portion in a straight shape extending in a predetermined first direction and a straight portion in a straight shape extending in a second direction perpendicular to the first direction is wound in a spiral shape from an outer peripheral side of the printed circuit board to its inner peripheral side, and a width of the conductor pattern in a direction perpendicular to a longitudinal direction of the conductor pattern is constant. When viewed in a thickness direction of the printed circuit board, in a case that a virtual square is set in which a length of 12 times of the width of the conductor pattern is a length of one side of the virtual square and four sides of the virtual square are in parallel to the first direction or the second direction, when viewed in the thickness direction of the printed circuit board, the virtual square disposed at a predetermined position includes a pattern part group comprised of a first pattern part, a second pattern part, a third pattern part and a fourth pattern part which structure a part of the conductor pattern. When one of the first direction and the second direction is referred to as a third direction and the other of the first direction and the second direction is referred to as a fourth direction, the first pattern part is structured of a first straight part which is formed in a straight shape and parallel to the third direction, and the second pattern part is structured of a second straight part which is formed in a straight shape and parallel to the third direction and is shorter than the first straight part, two third straight parts whose base ends are connected with both ends of the second straight part in the third direction and which are formed in a straight shape and parallel to the fourth direction so as to extend in the same direction, and two fourth straight parts which are formed in a straight shape and are extended from respective tip ends of the two third straight parts to outer sides in the third direction. The third pattern part is structured of a fifth straight part which is formed in a straight shape and parallel to the third direction and is shorter than the second straight part, two sixth straight parts whose base ends are connected with both ends of the fifth straight part in the third direction and which are formed in a straight shape and parallel to the fourth direction so as to extend in the same direction as the third straight part, and two seventh straight parts which are formed in a straight shape and are extended from respective tip ends of the two sixth straight parts to outer sides in the third direction. The fourth pattern part is structured of an eighth straight part which is formed in a straight shape and parallel to the third direction and is shorter than the fifth straight part, two ninth straight parts whose base ends are connected with both ends of the eighth straight part in the third direction and which are formed in a straight shape and parallel to the fourth direction so as to extend in the same direction as the third straight part, and two tenth straight parts which are formed in a straight shape and are extended from respective tip ends of the two ninth straight parts to outer sides in the third direction. The first pattern part, the second pattern part, the third pattern part and the fourth pattern part are arranged in this order in the fourth direction so that a center of the first straight part in the third direction, a center of the second straight part in the third direction, a center of the fifth straight part in the third direction, and a center of the eighth straight part in the third direction are coincided with each other in the third direction. A space between the first straight part and the second straight part in the fourth direction, a space between the second straight part and the fifth straight part in the fourth direction, a space between the fifth straight part and the eighth straight part in the fourth direction and the width of the conductor pattern are equal to each other, a length of the third straight part, a length of the sixth straight part and a length of the ninth straight part are equal to each other, and the second straight part is shorter than the first straight part by the same distance as the width of the conductor pattern, the fifth straight part is shorter than the second straight part by the same distance as 4 times of the width of the conductor pattern, and the eighth straight part is shorter than the fifth straight part by the same distance as 4 times of the width of the conductor pattern. A space in the third direction of the two ninth straight parts is equal to the width of the conductor pattern. At least a part of the destruction detection pattern is structured by combining the pattern part groups so that the first straight part and the fourth straight part are connected with each other, the seventh straight part and the tenth straight part are connected with each other, and that extending directions of the third straight part, the sixth straight part and the ninth straight part of adjacent pattern part groups are different from each other.

Further, according to at least an embodiment of the present invention, there may be provided a printed circuit board formed in a plate shape or a film shape, including a destruction detection pattern for detecting its own disconnection and/or its own short circuit. The destruction detection pattern is formed so that a conductor pattern structured by a combination of a straight portion in a straight shape or a substantially straight shape extending in a predetermined first direction and a straight portion in a straight shape or a substantially straight shape extending in a second direction perpendicular to the first direction is wound in a spiral shape from an outer peripheral side of the printed circuit board to its inner peripheral side, and a width of the conductor pattern in a direction perpendicular to a longitudinal direction of the conductor pattern is constant. When viewed in a thickness direction of the printed circuit board, in a case that a virtual square is set in which a length of 12 times of the width of the conductor pattern is a length of one side of the virtual square and four sides of the virtual square are in parallel to the first direction or the second direction, when viewed in the thickness direction of the printed circuit board, the virtual square disposed at a predetermined position includes a pattern part group comprised of a first pattern part, a second pattern part, a third pattern part and a fourth pattern part which structure a part of the conductor pattern. When one of the first direction and the second direction is referred to as a third direction and the other of the first direction and the second direction is referred to as a fourth direction, the first pattern part is structured of a first straight part which is formed in a straight shape and parallel to the third direction, and the second pattern part is structured of a second straight part which is formed in a straight shape and parallel to the third direction and is shorter than the first straight part, two third straight parts whose base ends are connected with both ends of the second straight part in the third direction and which are formed in a substantially straight shape and substantially parallel to the fourth direction so as to extend in a substantially same direction, and two fourth straight parts which are formed in a substantially straight shape and are extended from respective tip ends of the two third straight parts to outer sides in the third direction. The third pattern part is structured of a fifth straight part which is formed in a straight shape and parallel to the third direction and is shorter than the second straight part, two sixth straight parts whose base ends are connected with both ends of the fifth straight part in the third direction and which are formed in a substantially straight shape and substantially parallel to the fourth direction so as to extend in a substantially same direction as the third straight part, and two seventh straight parts which are formed in a straight shape and are extended from respective tip ends of the two sixth straight parts to outer sides in the third direction. The fourth pattern part is structured of an eighth straight part which is formed in a substantially straight shape and substantially parallel to the third direction and is shorter than the fifth straight part, two ninth straight parts whose base ends are connected with both ends of the eighth straight part in the third direction and which are formed in a straight shape and substantially parallel to the fourth direction so as to extend in a substantially same direction as the third straight part, and two tenth straight parts which are formed in a straight shape and are extended from respective tip ends of the two ninth straight parts to outer sides in the third direction. The first pattern part, the second pattern part, the third pattern part and the fourth pattern part are arranged in this order in the fourth direction so that a center of the first straight part in the third direction, a center of the second straight part in the third direction, a center of the fifth straight part in the third direction, and a center of the eighth straight part in the third direction are coincided with each other in the third direction, and a space between the first straight part and the second straight part in the fourth direction, a space between the second straight part and the fifth straight part in the fourth direction, a space between the fifth straight part and the eighth straight part in the fourth direction and the width of the conductor pattern are equal to each other. A length of the third straight part, a length of the sixth straight part and a length of the ninth straight part are equal to each other, the second straight part is shorter than the first straight part by a substantially same distance as the width of the conductor pattern, the fifth straight part is shorter than the second straight part by a substantially same distance as 4 times of the width of the conductor pattern, and the eighth straight part is shorter than the fifth straight part by a substantially same distance as 4 times of the width of the conductor pattern. A space in the third direction of the two ninth straight parts is substantially equal to the width of the conductor pattern. At least a part of the destruction detection pattern is structured by combining the pattern part groups so that the first straight part and the fourth straight part are connected with each other, the seventh straight part and the tenth straight part are connected with each other, and that extending directions of the third straight part, the sixth straight part and the ninth straight part of adjacent pattern part groups are different from each other.

The printed circuit board in accordance with at least an embodiment of the present invention is structured as described above and thus the conductor patterns themselves can be arranged in a combined relationship of projections and recesses in a region where pattern part groups are combined. Therefore, according to at least an embodiment of the present invention, even when a space between the conductor patterns structuring a destruction detection pattern is set to be relatively wide, in a case that the printed circuit board is cut by a cutter or the like, the destruction detection pattern is easily cut and, in a case that some illegal work is performed on the printed circuit board, the destruction detection pattern is easily short-circuited. As a result, according to at least an embodiment of the present invention, even when a space between the conductor patterns structuring a destruction detection pattern is set to be relatively wide, a security property of a device to which the printed circuit board is attached is secured. Therefore, according to the present invention, while securing a security property of a device to which the printed circuit board is attached, cost of the printed circuit board can be reduced and the destruction detection pattern can be formed easily.

Further, in the printed circuit board in accordance with at least an embodiment of the present invention, at least a part of the destruction detection pattern is structured by combining the pattern part groups. Therefore, even when the printed circuit board is formed in a complicated shape other than a square shape or a rectangular shape or, even when a hole is formed in the printed circuit board, the destruction detection pattern can be formed easily.

The printed circuit board in accordance with at least an embodiment of the present invention may be applied to a card reader which includes a rigid circuit board and a flexible printed circuit board as the printed circuit board, a card reader main body to which the rigid circuit board is attached, and a case body which covers the card reader main body. In the card reader, for example, the case body includes a first case body and a second case body which are divided in a thickness direction of the rigid circuit board, and the first case body covers the rigid circuit board and the flexible printed circuit board is stuck to an inner side face of the second case body so as to cover the entire inner side face of the second case body. In the card reader, even when a space between the conductor patterns structuring a destruction detection pattern is made relatively wide, a security property of the card reader can be secured.

In at least an embodiment of the present invention, one end of the conductor pattern of the rigid circuit board and one end of the conductor pattern of the flexible printed circuit board are serially-connected with each other, one of the other end of the conductor pattern of the rigid circuit board and the other end of the conductor pattern of the flexible printed circuit board is connected with a destruction detection circuit, and the other of the other end of the conductor pattern of the rigid circuit board and the other end of the conductor pattern of the flexible printed circuit board is grounded. According to this structure, even when the destruction detection pattern is formed in the rigid circuit board and the flexible printed circuit board, a circuit structure of the card reader can be simplified.

Other features and advantages of the invention will be apparent from the following detailed description, taken in conjunction with the accompanying drawings that illustrate, by way of example, various features of embodiments of the invention.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a perspective view showing a card reader in accordance with an embodiment of the present invention.

FIG. 2 is an exploded perspective view showing a state that a case body has been detached from the card reader shown in FIG. 1.

FIG. 3 is a view showing a destruction detection pattern of a printed circuit board shown in FIG. 2.

FIG. 4 is an enlarged view showing a part of the destruction detection pattern shown in FIG. 3.

FIG. 5 is an enlarged view showing a part of the destruction detection pattern shown in FIG. 4.

FIG. 6 is a view showing a destruction detection pattern of a flexible printed circuit board which is stuck on an inner side face of a second case body shown in Fig.

FIG. 7 is an enlarged view showing a part of the destruction detection pattern shown in FIG. 6.

FIG. 8 is an enlarged view showing the “E” part in FIG. 6.

### DETAILED DESCRIPTION OF THE PREFERRED EMBODIMENTS

An embodiment of the present invention will be described below with reference to the accompanying drawings.

### (Entire Structure of Card Reader)

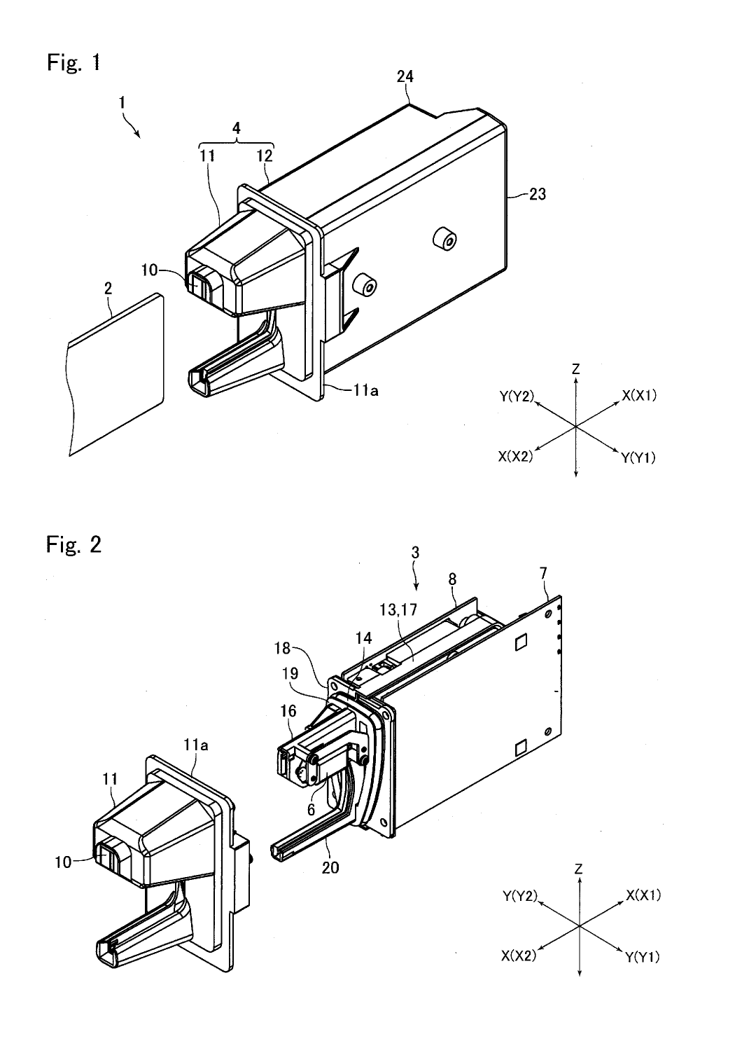

FIG. 1 is a perspective view showing a card reader 1 in accordance with an embodiment of the present invention. FIG. 2 is an exploded perspective view showing a state that a case body 4 has been detached from the card reader 1 shown in FIG. 1. In FIG. 2, a case main body 12 is not shown.

A card reader 1 in this embodiment is a device in which a user manually operates a card 2 to perform reading of data recorded in a card 2 and recording of data to a card 2. Specifically, the card reader 1 is a so-called dip-type card reader in which insertion of a card 2 to the card reader 1 and extraction of the card 2 from the card reader 1 are manually performed to execute reading of data and recording of data. The card reader 1 is, for example, mounted on and used in a host device such as an oiling device of an unattended or self-service gas station.

A card 2 is, for example, a rectangular card made of vinyl chloride whose thickness is about 0.7-0.8 mm. A magnetic stripe in which magnetic data are recorded is formed on one of faces of the card 2. Further, an IC chip is incorporated in the card 2. An external connection terminal of an IC chip is formed on the other of the faces of the card 2. The card 2 may be a PET (polyethylene terephthalate) card whose thickness is about 0.18-0.36 mm or a paper card having a predetermined thickness.

The card reader 1 is structured of a card reader main body 3 and a case body 4 which covers the card reader main body 3. The card reader main body 3 includes a magnetic head 6 structured to perform reading of magnetic data recorded on a card 2 and recording magnetic data on the card 2 and an IC contact block (not shown) having a plurality of IC contacts for performing data communication with an IC chip incorporated in the card 2. The card reader main body 3 is attached with a printed circuit board 7 with which lead wires (not shown) extended from the magnetic head 6 are connected and a printed circuit board 8 with which a cable (specifically, flexible printed circuit board) extended from the IC contact block is connected.

The case body 4 is structured of a front face cover 11 which is formed with an insertion port 10 for a card 2 and a case main body 12. The card reader main body 3 includes a main body frame 13 which is fixed to the front face cover 11 and is accommodated into the case main body 12 and a seal member 14 which is disposed between the front face cover 11 and the main body frame 13. The seal member 14 is formed of rubber or the like and is formed in a ring shape.

In this embodiment, a card 2 which is manually operated is moved in an “X” direction in FIG. 1 and the like. Specifically, a card 2 is inserted in an “X1” direction and the card 2 is extracted in an “X2” direction. Further, a “Y” direction perpendicular to the “X” direction in FIG. 1 and the like is a thickness direction of a card 2 inserted into the card reader 1 and a “Z” direction perpendicular to the “X” direction and the “Y” direction in FIG. 1 and the like is a widthwise direction (short widthwise direction) of a card 2 inserted into the card reader 1. In the following descriptions, the “X” direction is referred to as a front and rear direction, the “Y” direction is referred to as a right and left direction, and the “Z” direction is an upper and lower direction. Further, an “X1” direction side is referred to as a “rear” (back) side, an “X2” direction side is referred to as a “front” side, a “Y1” direction side is referred to as a “right” side, and a “Y2” direction side is a “left” side.

The main body frame 13 is provided with a head arrangement part 16 in which the magnetic head 6 is disposed, a bag-shaped card accommodation part 17 in which a rear end side of a card 2 inserted through the insertion port 10 is accommodated, a partition part 18 which is formed between the head arrangement part 16 and the card accommodation part 17, a seal arrangement part 19 which is formed between the head arrangement part 16 and the partition part 18 and in which a seal member 14 is disposed, and a card guide part 20 structured to guide a card 2 inserted through the insertion port 10.

Rear ends of the head arrangement part 16 and the card guide part 20 are connected with a front end of the seal arrangement part 19, a rear end of the seal arrangement part 19 is connected with a front end of the partition part 18, and a rear end of the partition part 18 is connected with a front end of the card accommodation part 17. The head arrangement part 16 and the card guide part 20 are formed so as to protrude to a front side from the seal arrangement part 19. Further, the head arrangement part 16 and the card guide part 20 are formed with a space therebetween in the upper and lower direction. An IC contact block is attached to the card accommodation part 17. The printed circuit board 7 is fixed to a right side face of the card accommodation part 17 and the printed circuit board 8 is fixed to a left side face of the card accommodation part 17.

The front face cover 11 covers a front side portion of the main body frame 13 with respect to the partition part 18. A flange part 11a formed in a flange shape is formed on a rear face side of the front face cover 11. The flange part 11a is formed in a substantially rectangular frame shape which is long in the upper and lower direction. The case main body 12 is formed in a substantially rectangular box shape whose front end is opened. The case main body 12 is fixed to the front face cover 11 in a state that its front end is abutted with a rear face of the flange part 11a. A portion of the main body frame 13 on a rear side with respect to the partition part 18 is disposed in an inside of the case main body 12 and the case main body 12 covers the portion of the main body frame 13 on the rear side with respect to the partition part 18.

The case main body 12 is structured of a first case body 23 and a second case body 24 which are divided into two pieces in the right and left direction. The first case body 23 structures a right side portion of the case main body 12 and the second case body 24 structures a left side portion of the case main body 12. Further, the first case body 23 is structured of a right side face part which structures a right side face of the case main body 12, upper and lower side face parts which structure parts of upper and lower side faces of the case main body 12, and a rear side face part structuring a part of a rear face of the case main body 12. The second case body 24 is structured of a left side face part which structures a left side face of the case main body 12, upper and lower side faces which structure parts of upper and lower side faces of the case main body 12, and a rear side face part which structures a part of a rear face of the case main body 12. In this embodiment, a width in the right and left direction of the first case body 23 is narrower than a width in the right and left direction of the second case body 24. The first case body 23 covers a part of the card reader main body 3 (specifically, a rear side portion of the card reader main body 3 with respect to the partition part 18) and the printed circuit board 7 from a right side and from both upper and lower sides. The second case body 24 covers a part of the card reader main body 3 (specifically, a rear side portion of the card reader main body 3 with respect to the partition part 18) and the printed circuit board 8 from a left side and both upper and lower sides.

The printed circuit boards 7 and 8 are rigid circuit boards having rigidity. The printed circuit boards 7 and 8 are formed in a rectangular flat plate shape. Further, the printed circuit boards 7 and 8 are fixed to the card reader main body 3 so that their thickness directions are coincided with the right and left direction. In other words, the right and left direction is thickness directions of the printed circuit boards 7 and 8.

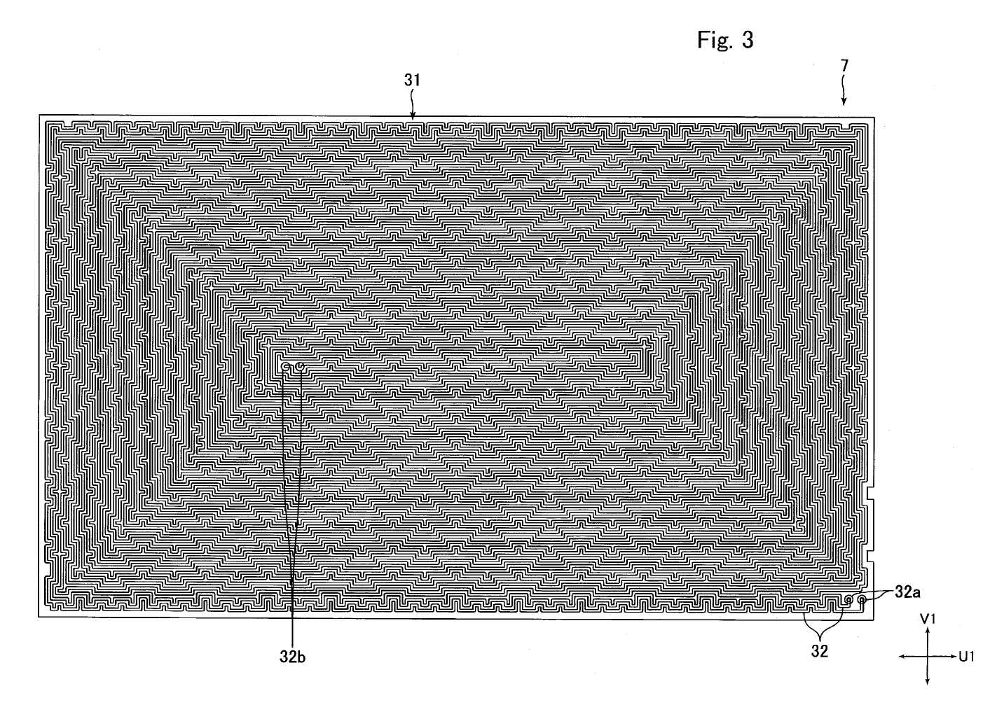

The printed circuit board 7 is provided with a signal pattern layer which is formed with a signal pattern for transmitting a signal of magnetic data (data signal) having been read from a magnetic stripe of a card 2 by the magnetic head 6 and for transmitting a data signal which is to be recorded in the magnetic stripe of the card 2 by the magnetic head 6. Further, the printed circuit board 7 is provided with a destruction detection pattern layer which is formed with a destruction detection pattern 31 (see FIG. 3) for detecting that the printed circuit board 7 itself is disconnected and short-circuited. The destruction detection pattern layer is formed so as to cover the signal pattern layer. A specific structure of the destruction detection pattern 31 will be described below.

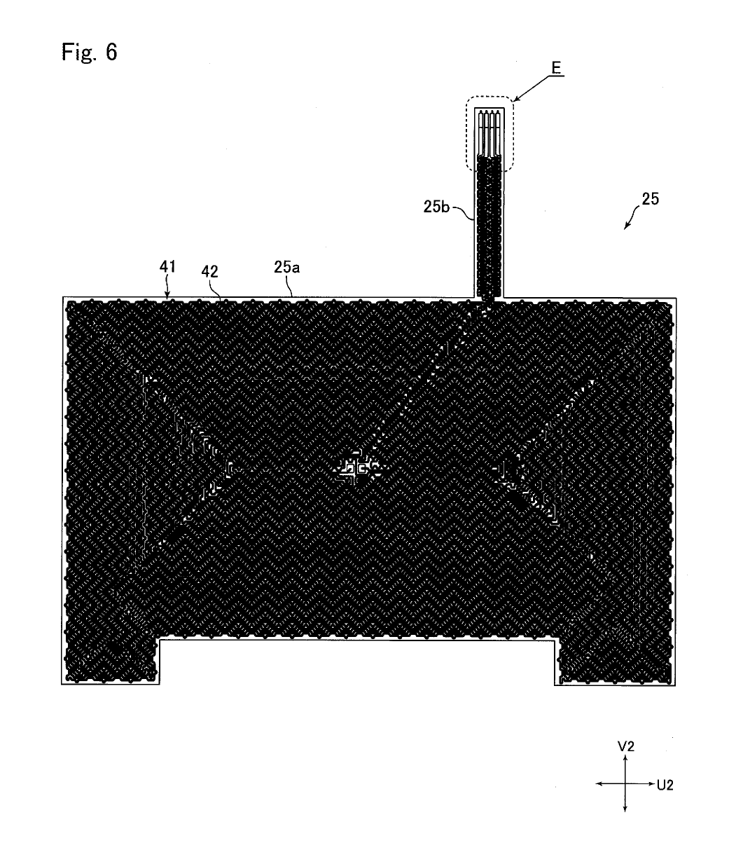

The printed circuit board 8 is provided with a signal pattern layer which is formed with a signal pattern and the like for transmitting a signal of data (data signal) having been read from an IC chip of a card 2 through the IC contacts and for transmitting a data signal which is to be recorded in the IC chip of the card 2 through the IC contacts. In this embodiment, a flexible printed circuit board 25 (see FIG. 6, hereinafter, referred to as an FPC 25) as a printed circuit board is stuck to an inner side face of the second case body 24. Specifically, the FPC 25 is stuck to the inner side face of the second case body 24 so as to cover the entire inner peripheral face of the second case body 24 along the inner side face of the second case body 24. The FPC 25 is provided with a destruction detection pattern layer in which a destruction detection pattern 41 is formed for detecting its own disconnection and short circuit. Further, as described above, the second case body 24 covers the printed circuit board 8 from a left side. In other words, the printed circuit board 8 is covered by the destruction detection pattern 41. Therefore, the printed circuit board 8 is not formed with a destruction detection pattern. A specific structure of the FPC 25 will be described below.

(Structures of Destruction Detection Patterns of Rigid Circuit Board and Flexible Printed Circuit Board)

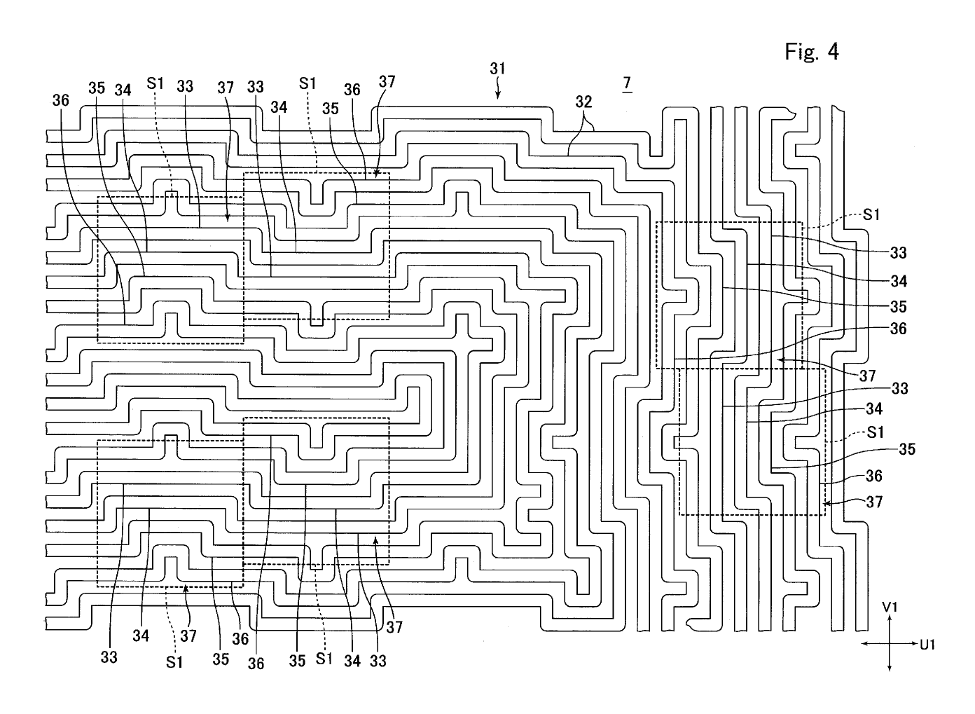

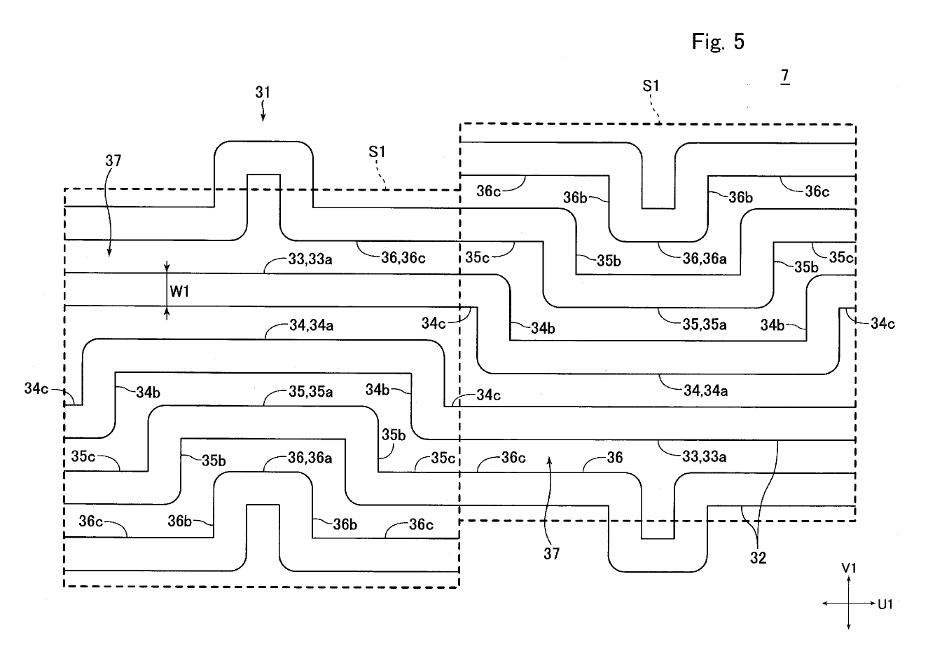

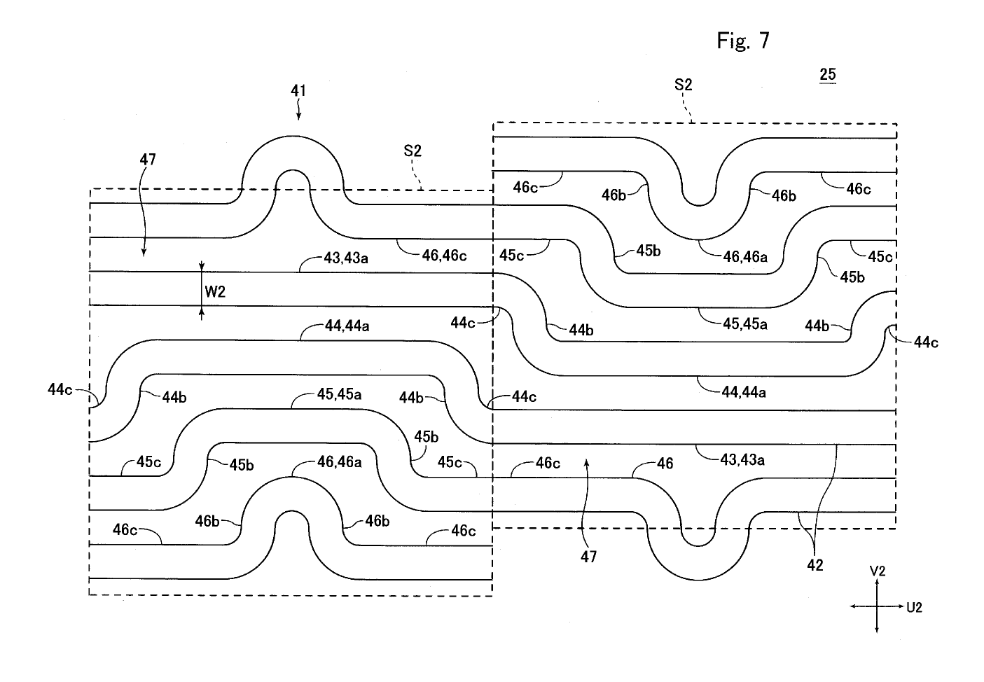

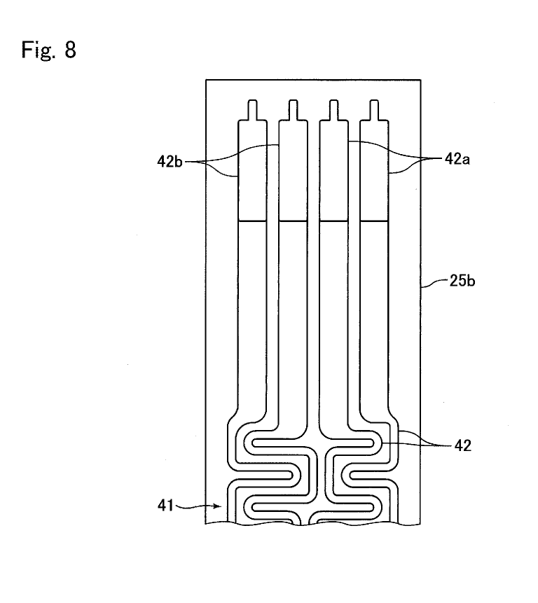

FIG. 3 is a view showing the destruction detection pattern 31 of the printed circuit board 7 shown in FIG. 2. FIG. 4 is an enlarged view showing a part of the destruction detection pattern 31 shown in FIG. 3. FIG. 5 is an enlarged view showing a part of the destruction detection pattern 31 shown in FIG. 4. FIG. 6 is a view showing the destruction detection pattern 41 of the flexible printed circuit board 25 which is stuck on the inner side face of the second case body 24 shown in FIG. 1. FIG. 7 is an enlarged view showing a part of the destruction detection pattern 41 shown in FIG. 6. FIG. 8 is an enlarged view showing the “E” part in FIG. 6.

As described above, the printed circuit board 7 is formed with the destruction detection pattern 31. The destruction detection pattern 31 is formed so that one pair (2 pieces) of conductor patterns 32 formed in a line shape is wound in a spiral shape from an outer peripheral side to an inner peripheral side of the printed circuit board 7 formed in a rectangular shaped (in other words, wound in a spiral shape from the inner peripheral side to the outer peripheral side of the printed circuit board 7). The conductor pattern 32 can also be referred to as a conductor. When a direction of a long side of the printed circuit board 7 formed in a rectangular shape is set to be a “U1” direction and a direction of a short side of the printed circuit board 7 perpendicular to the “U1” direction is set to be a “V1” direction, the conductor pattern 32 is structured of a combination of a straight portion in a straight shape extending in the “U1” direction and a straight portion in a straight shape extending in the “V1” direction. Further, a width “W1” of the conductor pattern 32 (see FIG. 5) in a direction perpendicular to the longitudinal direction of the conductor pattern 32 (route direction of the conductor pattern 32) is set to be constant.

In a case that, when viewed in a thickness direction of the printed circuit board 7, a virtual square “S1” is set so that a length of 12 times of the width “W1” of the conductor pattern 32 is a length of one side and four sides of the square are parallel to the “U1” direction or the “V1” direction, as shown in FIGS. 4 and 5, when viewed in the thickness direction of the printed circuit board 7, the virtual square “S1” disposed at a predetermined position includes a pattern part group 37 comprised of a first pattern part 33, a second pattern part 34, a third pattern part 35 and a fourth pattern part 36, which structures a part of the conductor pattern 32.

As shown in FIG. 5, in a portion extended along the “U1” direction of the conductor pattern 32, the first pattern part 33 is structured of a first straight part 33a which is formed in a straight shape so as to be parallel to the “U1” direction. Further, in a portion extended along the “U1” direction of the conductor pattern 32, the second pattern part 34 is structured of a second straight part 34a, which is formed in a straight shape and parallel to the “U1” direction and is shorter than the first straight part 33a, two third straight parts 34b in a straight shape whose base ends are respectively connected with both ends of the second straight part 34a in the “U1” direction and which are extended in the same direction so as to be parallel to the “V1” direction, and two fourth straight parts 34c in a straight shape which are extended to outer sides in the “U1” direction from respective tip ends of the two third straight parts 34b.

In addition, in a portion extended along the “U1” direction of the conductor pattern 32, the third pattern part 35 is structured of a fifth straight part 35a, which is formed in a straight shape and parallel to the “U1” direction and is shorter than the second straight part 34a, two sixth straight parts 35b in a straight shape whose base ends are respectively connected with both ends of the fifth straight part 35a in the “U1” direction and which are extended in the same direction as the third straight part 34b so as to be parallel to the “V1” direction, and two seventh straight parts 35c in a straight shape which are extended to outer sides in the “U1” direction from respective tip ends of the two sixth straight parts 35b. Further, in a portion extended along the “U1” direction of the conductor pattern 32, the fourth pattern part 36 is structured of an eighth straight part 36a, which is formed in a straight shape and parallel to the “U1” direction and is shorter than the fifth straight part 35a, two ninth straight parts 36b in a straight shape whose base ends are respectively connected with both ends of the eighth straight part 36a in the “U1” direction and which are extended in the same direction as the third straight part 34b so as to be parallel to the “V1” direction, and two tenth straight parts 36c in a straight shape which are extended to outer sides in the “U1” direction from respective tip ends of the two ninth straight parts 36b.

Similarly, in a portion extended along the “V1” direction of the conductor pattern 32, the first pattern part 33 is structured the first straight part 33a which is formed in a straight shape so as to be parallel to the “V1” direction. Further, in a portion extended along the “V1” direction of the conductor pattern 32, the second pattern part 34 is structured of the second straight part 34a, which is formed in a straight shape and parallel to the “V1” direction and is shorter than the first straight part 33a, two third straight parts 34b in a straight shape whose base ends are respectively connected with both ends of the second straight part 34a in the “V1” direction and which are extended in the same direction and parallel to the “U1” direction, and two fourth straight parts 34c in a straight shape which are extended to outer sides in the “V1” direction from respective tip ends of the two third straight parts 34b.

In addition, in a portion extended along the “V1” direction of the conductor pattern 32, the third pattern part 35 is structured of the fifth straight part 35a, which is formed in a straight shape and parallel to the “V1” direction and is shorter than the second straight part 34a, two sixth straight parts 35b in a straight shape whose base ends are respectively connected with both ends of the fifth straight part 35a in the “V1” direction and which are extended in the same direction as the third straight part 34b so as to be parallel to the “U1” direction, and two seventh straight parts 35c in a straight shape which are extended to outer sides in the “V1” direction from respective tip ends of the two sixth straight parts 35b. Further, in a portion extended along the “V1” direction of the conductor pattern 32, the fourth pattern part 36 is structured of the eighth straight part 36a, which is formed in a straight shape and parallel to the “V1” direction and is shorter than the fifth straight part 35a, two ninth straight parts 36b in a straight shape whose base ends are respectively connected with both ends of the eighth straight part 36a in the “V1” direction and which are extended in the same direction as the third straight part 34b so as to be parallel to the “U1” direction, and two tenth straight parts 36c in a straight shape which are extended to outer sides in the “V1” direction from respective tip ends of the two ninth straight parts 36b.

In a portion of the conductor pattern 32 extended along the “U1” direction, the first pattern part 33, the second pattern part 34, the third pattern part 35 and the fourth pattern part 36 are arranged in this order in the “V1” direction so that a center of the first straight part 33a in the “U1” direction, a center of the second straight part 34a in the “U1” direction, a center of the fifth straight part 35a in the “U1” direction, and a center of the eighth straight part 36a in the “U1” direction are coincided with each other in the “U1” direction. Further, in a portion of the conductor pattern 32 extended along the “U1” direction, a space between the first straight part 33a and the second straight part 34a in the “V1” direction, a space between the second straight part 34a and the fifth straight part 35a in the “V1” direction, a space between the fifth straight part 35a and the eighth straight part 36a in the “V1” direction, and the width “W1” of the conductor pattern 32 are set to be equal to each other.

Similarly, in a portion of the conductor pattern 32 extended along the “V1” direction, the first pattern part 33, the second pattern part 34, the third pattern part 35 and the fourth pattern part 36 are arranged in this order in the “U1” direction so that a center of the first straight part 33a in the “V1” direction, a center of the second straight part 34a in the “V1” direction, a center of the fifth straight part 35a in the “V1” direction, and a center of the eighth straight part 36a in the “V1” direction are coincided with each other in the “V1” direction. Further, in a portion of the conductor pattern 32 extended along the “V1” direction, a space between the first straight part 33a and the second straight part 34a in the “U1” direction, a space between the second straight part 34a and the fifth straight part 35a in the “U1” direction, a space between the fifth straight part 35a and the eighth straight part 36a in the “U1” direction, and the width “W1” of the conductor pattern 32 are set to be equal to each other.

A length of the third straight part 34b, a length of the sixth straight part 35b and a length of the ninth straight part 36b are set to be equal to each other. Further, the second straight part 34a is set to be shorter than the first straight part 33a by the same distance as the width “W1” of the conductor pattern 32. The fifth straight part 35a is shorter than the second straight part 34a by the same distance as 4 times of the width “W1” of the conductor pattern 32. The eighth straight part 36a is shorter than the fifth straight part 35a by the same distance as 4 times of the width “W1” of the conductor pattern 32. Further, a space between two ninth straight parts 36b is set to be equal to the width “W1” of the conductor pattern 32. In other words, in a portion of the conductor pattern 32 extended along the “U1” direction, a space between the two ninth straight parts 36b in the “U1” direction is equal to the width “W1” of the conductor pattern 32 and, in a portion of the conductor pattern 32 extended along the “V1” direction, a space between the two ninth straight parts 36b in the “V1” direction is equal to the width “W1” of the conductor pattern 32.

Further, the first through the fourth pattern parts 33 through 36 are formed as described above and thus, in the portion of the conductor pattern 32 extended along the “U1” direction, the fifth straight part 35a is disposed between two fourth straight parts 34c in the “U1” direction and, in the “V1” direction, the fourth straight part 34c and the fifth straight part 35a are disposed at the same position as each other. Further, the eighth straight part 36a is disposed between two seventh straight parts 35c in the “U1” direction and, in the “V1” direction, the seventh straight part 35c and the eighth straight part 36a are disposed at the same position as each other. Similarly, in the portion of the conductor pattern 32 extended along the “V1” direction, the fifth straight part 35a is disposed between two fourth straight parts 34c in the “V1” direction and, in the “U1” direction, the fourth straight part 34c and the fifth straight part 35a are disposed at the same position as each other. Further, the eighth straight part 36a is disposed between two seventh straight parts 35c in the “V1” direction and, in the “U1” direction, the seventh straight part 35c and the eighth straight part 36a are disposed at the same position as each other.

In this embodiment, a part of the destruction detection pattern 31 is structured by combining a plurality of pattern part groups 37 so that the first straight part 33a is connected with the fourth straight part 34c and the seventh straight part 35c is connected with the tenth straight part 36c and, so that extending directions of the third straight parts 34b, the sixth straight parts 35b and the ninth straight parts 36b of adjacent pattern part groups 37 are different from each other (specifically, so that extending directions of the third straight parts 34b, the sixth straight parts 35b and the ninth straight parts 36b with respect to the second straight part 34a, the fifth straight part 35a and the eighth straight part 36a are different from each other). Specifically, in the destruction detection pattern 31, except for an outer peripheral side portion of the printed circuit board 7, a part of a center side portion of the printed circuit board 7, and portions where the conductor pattern 32 extended along one of the “U1” direction and the “V1” direction is bent at 90° to the other of the “U1” direction and the “V1” direction, a part of the destruction detection pattern 31 is structured by combining a plurality of the pattern part groups 37 so that the first straight part 33a is connected with the fourth straight part 34c, the seventh straight part 35c is connected with the tenth straight part 36c, and extending directions of the third straight parts 34b, the sixth straight parts 35b and the ninth straight parts 36b of adjacent pattern part groups 37 are different from each other.

In this embodiment, the “U1” direction is a first direction and the “V1” direction is a second direction. Further, in this embodiment, in a portion of the conductor pattern 32 extended along the “U1” direction, the “U1” direction is a third direction and the “V1” direction is a fourth direction. On the other hand, in a portion of the conductor pattern 32 extended along the “V1” direction, the “U1” direction is the fourth direction and the “V1” direction is the third direction.

The FPC 25 is formed in a film shape having flexibility. Further, the FPC 25 is formed in a substantially rectangular shape as a whole. The FPC 25 is formed with the destruction detection pattern 41 as described above. The destruction detection pattern 41 is formed so that one pair (2 pieces) of conductor patterns 42 formed in a line shape is wound in a spiral shape from an outer peripheral side to an inner peripheral side of the FPC 25 formed in a rectangular shaped (in other words, wound in a spiral shape from the inner peripheral side to the outer peripheral side of the FPC 25). In this embodiment, the destruction detection pattern 41 is formed of a pair of the conductor patterns 42 which are wound from an outer peripheral side of the FPC 25 to its inner peripheral side in a spiral shape and from the inner peripheral side of the FPC 25 to its outer peripheral side in a spiral shape again.

Further, the FPC 25 is structured of a base part 25a which is stuck on an inner side face of the second case body 24 and an extended part 25b for leading out the conductor pattern 42 from the base part 25a. The base part 25a is formed in a substantially rectangular shape. The extended part 25b is formed in a long and thin band shape. The destruction detection pattern 41 is formed in both of the base part 25a and the extended part 25b.

When a direction of a long side of the base part 25a formed in a substantially rectangular shape is set to be a “U2” direction and a direction of a short side of the base part 25a perpendicular to the “U2” direction is set to be a “V2” direction, the conductor pattern 42 is structured of a combination of a straight portion in a straight shape or a substantially straight shape which is extended in the “U2” direction and a straight portion in a straight shape or a substantially straight shape which is extended in the “V2” direction. Further, a width “W2” (see FIG. 7) of the conductor pattern 42 in a direction perpendicular to a longitudinal direction of the conductor pattern 42 (route direction of the conductor pattern 42) is constant.

In a case that, when viewed in a thickness direction of the FPC 25, a virtual square “S2” is set so that a length of 12 times of the width “W2” of the conductor pattern 42 is a length of one side of the virtual square “S2” and four sides of the square are parallel to the “U2” direction or the “V2” direction, similarly to the printed circuit board 7, when viewed in the thickness direction of the FPC 25, the virtual square “S2” disposed at a predetermined position includes a pattern part group 47 which is comprised of a first pattern part 43, a second pattern part 44, a third pattern part 45 and a fourth pattern part 46 structuring a part of the conductor pattern 42 (see FIG. 7). Each of the first through the fourth pattern parts 43 through 46 is structured substantially similarly to each of the first through the fourth pattern parts 33 through 36.

In other words, in a portion of the conductor pattern 42 extended along the “U2” direction, the first pattern part 43 is structured of a first straight part 43a which is formed in a straight shape and parallel to the “U2” direction. Further, in a portion of the conductor pattern 42 extended along the “U2” direction, the second pattern part 44 is structured of a second straight part 44a, which is formed in a straight shape and parallel to the “U2” direction and is shorter than the first straight part 43a, two third straight parts 44b in a substantially straight shape whose base ends are respectively connected with both ends of the second straight part 44a in the “U2” direction and which are extended in a substantially same direction and substantially parallel to the “V2” direction, and two fourth straight parts 44c in a substantially straight shape which are extended to outer sides in the “U2” direction from respective tip ends of the two third straight parts 44b.

In addition, in a portion of the conductor pattern 42 extended along the “U2” direction, the third pattern part 45 is structured of a fifth straight part 45a, which is formed in a straight shape and parallel to the “U2” direction and is shorter than the second straight part 44a, two sixth straight part 45b in a substantially straight shape whose base ends are respectively connected with both ends of the fifth straight part 45a in the “U2” direction and which are extended in a substantially same direction as the third straight part 44b and substantially parallel to the “V2” direction, and two seventh straight parts 45c in a substantially straight shape which are extended to outer sides in the “U2” direction from respective tip ends of the two sixth straight parts 45b. Further, in a portion extended along the “U2” direction of the conductor pattern 42, the fourth pattern part 36 is structured of an eighth straight part 46a, which is formed in a substantially straight shape and substantially parallel to the “U2” direction (specifically, formed in a circular arc shape) and is shorter than the fifth straight part 45a, two ninth straight parts 46b in a substantially straight shape whose base ends are respectively connected with both ends of the eighth straight part 46a in the “U2” direction and which are extended in a substantially same direction as the third straight part 44b and substantially parallel to the “V2” direction, and two tenth straight parts 46c in a substantially straight shape which are extended to outer sides in the “U2” direction from respective tip ends of the two ninth straight parts 36b. In this case, the third straight part 44b formed in a substantially straight shape, the sixth straight part 45b formed in a substantially straight shape, and the ninth straight part 46b formed in a substantially straight shape may be, similarly to the eighth straight part 46a formed in a circular arc shape, regarded as a circular arc shaped part which is bent in a circular arc shape.

Similarly, in a portion of the conductor pattern 42 extended along the “V2” direction, the first pattern part 43 is structured of a first straight part 43a which is formed in a straight shape and parallel to the “V2” direction. Further, in a portion of the conductor pattern 42 extended along the “V2” direction, the second pattern part 44 is structured of a second straight part 44a, which is formed in a straight shape and parallel to the “V2” direction and is shorter than the first straight part 43a, two third straight parts 44b in a substantially straight shape whose base ends are respectively connected with both ends of the second straight part 44a in the “V2” direction and which are extended in a substantially same direction and substantially parallel to the “U2” direction, and two fourth straight parts 44c in a substantially straight shape which are extended to outer sides in the “V2” direction from respective tip ends of the two third straight parts 44b.

In addition, in a portion of the conductor pattern 42 extended along the “V2” direction, the third pattern part 45 is structured of a fifth straight part 45a, which is formed in a straight shape and parallel to the “V2” direction and is shorter than the second straight part 44a, two sixth straight parts 45b in a substantially straight shape whose base ends are respectively connected with both ends of the fifth straight part 45a in the “V2” direction and which are extended in the substantially same direction as the third straight part 44b and substantially parallel to the “U2” direction, and two seventh straight parts 45c in a substantially straight shape which are extended to outer sides in the “V2” direction from respective tip ends of the two sixth straight parts 45b. Further, in a portion of the conductor pattern 42 extended along the “V2” direction, the fourth pattern part 36 is structured of an eighth straight part 46a, which is formed in a substantially straight shape and substantially parallel to the “V2” direction (specifically, formed in a circular arc shape) and is shorter than the fifth straight part 45a, two ninth straight parts 46b in a substantially straight shape whose base ends are respectively connected with both ends of the eighth straight part 46a in the “V2” direction and which are extended in substantially the same direction as the third straight part 44b and substantially parallel to the “U2” direction, and two tenth straight parts 46c in a substantially straight shape which are extended to outer sides in the “V2” direction from respective tip ends of the two ninth straight parts 46b.

In a portion of the conductor pattern 42 extended along the “U2” direction, the first pattern part 43, the second pattern part 44, the third pattern part 45 and the fourth pattern part 46 are arranged in this order in the “V2” direction so that a center of the first straight part 43a in the “U2” direction, a center of the second straight part 44a in the “U2” direction, a center of the fifth straight part 45a in the “U2” direction, and a center of the eighth straight part 46a in the “U2” direction are coincided with each other in the “U2” direction. Further, in a portion of the conductor pattern 42 extended along the “U2” direction, a space between the first straight part 43a and the second straight part 44a in the “V2” direction, a space between the second straight part 44a and the fifth straight part 45a in the “V2” direction, a space between the fifth straight part 45a and the eighth straight part 46a in the “V2” direction, and the width “W2” of the conductor pattern 42 are set to be equal to each other.

Similarly, in a portion of the conductor pattern 42 extended along the “V2” direction, the first pattern part 43, the second pattern part 44, the third pattern part 45 and the fourth pattern part 46 are arranged in this order in the “U2” direction so that a center of the first straight part 43a in the “V2” direction, a center of the second straight part 44a in the “V2” direction, a center of the fifth straight part 45a in the “V2” direction, and a center of the eighth straight part 46a in the “V2” direction are coincided with each other in the “V2” direction. Further, in a portion of the conductor pattern 42 extended along the “V2” direction, a space between the first straight part 43a and the second straight part 44a in the “U2” direction, a space between the second straight part 44a and the fifth straight part 45a in the “U2” direction, a space between the fifth straight part 45a and the eighth straight part 46a in the “U2” direction, and the width “W2” of the conductor pattern 42 are set to be equal to each other.

A length of the third straight part 44b, a length of the sixth straight part 45b and a length of the ninth straight part 46b are set to be equal to each other. Further, the second straight part 4a is set to be shorter than the first straight part 43a by a substantially same distance as the width “W2” of the conductor pattern 42. The fifth straight part 45a is shorter than the second straight part 44a by a substantially same distance as 4 times of the width “W2” of the conductor pattern 42. The eighth straight part 46a is shorter than the fifth straight part 45a by a substantially same distance as 4 times of the width “W2” of the conductor pattern 42. Further, a space between two ninth straight parts 46b is set to be substantially equal to the width “W2” of the conductor pattern 42. In other words, in a portion of the conductor pattern 42 extended along the “U2” direction, a space between two ninth straight parts 46b in the “U2” direction is substantially equal to the width “W2” of the conductor pattern 42 and, in a portion of the conductor pattern 42 extended along “V2” direction, a space between two ninth straight part 46b in the “V2” direction is substantially equal to the width “W2” of the conductor pattern 42.

Further, the first through the fourth pattern parts 43 through 46 are formed as described above and thus, in the portion of the conductor pattern 42 extended along the “U2” direction, the fifth straight part 45a is disposed between two fourth straight parts 44c in the “U2” direction and, in the “V2” direction, the fourth straight part 44c and the fifth straight part 45a are disposed at the same position as each other. Further, the eighth straight part 46a is disposed between two seventh straight parts 45c in the “U2” direction and, in the “V2” direction, the seventh straight part 45c and the eighth straight part 46a are disposed at the same position as each other. Similarly, in the portion of the conductor pattern 42 extended along the “V2” direction, the fifth straight part 45a is disposed between two fourth straight parts 44c in the “V2” direction and, in the “U2” direction, the fourth straight part 44c and the fifth straight part 45a are disposed at the same position as each other. Further, the eighth straight part 46a is disposed between two seventh straight parts 45c in the “V1” direction and, in the “U1” direction, the seventh straight part 45c and the eighth straight part 46a are disposed at the same position as each other.

In this embodiment, a part of the destruction detection pattern 41 is structured by combining a plurality of pattern part groups 47 so that the first straight part 43a is connected with the fourth straight part 44c and the seventh straight part 45c is connected with the tenth straight part 46c and, so that extending directions of the third straight parts 44b, the sixth straight parts 45b and the ninth straight parts 46b of adjacent pattern part groups 47 are different from each other (specifically, so that extending directions of the third straight parts 44b, the sixth straight parts 45b and the ninth straight parts 46b with respect to the second straight part 44a, the fifth straight part 45a and the eighth straight part 46a are different from each other). Specifically, in the destruction detection pattern 41, except for an outer peripheral side portion of the base part 25a, a part of a center side portion of the base part 25a, portions where the conductor pattern 42 extended along one of the “U2” direction and the “V2” direction is bent at 90° to the other of the “U2” direction and the “V2” direction, the extended part 25b and the like, a part of the destruction detection pattern 41 is structured by combining a plurality of the pattern part groups 47 so that the first straight part 43a is connected with the fourth straight part 44c, the seventh straight part 45c is connected with the tenth straight part 46c, and extending directions of the third straight part 44b, the sixth straight part 45b and the ninth straight part 46b of adjacent pattern part groups 47 are different from each other.

In this embodiment, the “U2” direction is a first direction and the “V2” direction is a second direction. Further, in this embodiment, in a portion of the conductor pattern 42 extended along the “U2” direction, the “U2” direction is a third direction and the “V2” direction is a fourth direction. On the other hand, in a portion of the conductor pattern 42 extended along the “V2” direction, the “U2” direction is the fourth direction and the “V2” direction is the third direction.

One end of the conductor pattern 32 of the printed circuit board 7 and one end of the conductor pattern 42 of the FPC 25 are connected in series with each other. Further, one of the other end of the conductor pattern 32 and the other end of the conductor pattern 42 is connected with a destruction detection circuit (not shown) for detecting disconnection and short circuit of the destruction detection patterns 31 and 41, and the other of the other end of the conductor pattern 32 and the other end of the conductor pattern 42 is grounded. For example, terminals 32a (see FIG. 3) which are disposed at a corner part on an outer peripheral end side of the printed circuit board 7 to structure one end of a pair of the conductor patterns 32 are electrically connected in series with terminals 42a (see FIG. 8) which are disposed at an end part of the extended part 25b to structure one end of a pair of the conductor patterns 42. Further, one of terminals 32b which are disposed on a center side of the printed circuit board 7 to structure the other end of a pair of the conductor patterns 32 and terminals 42b which are disposed at the end part of the extended part 25b to structure the other end of a pair of the conductor patterns 42 is electrically connected with the destruction detection circuit and the other of the terminals 32b and the terminals 42b is grounded.

Further, one of the terminals 32b and the terminals 42b is connected with a power supply and a battery for backup through the destruction detection circuit. When a power supply of the card reader 1 is set in an “ON” state, electric power is supplied to the conductor patterns 32 and 42 from the power supply (in other words, electric power is supplied to the destruction detection patterns 31 and 41) and, when the power supply of the card reader 1 is set in an “OFF” state, electric power is supplied to the conductor patterns 32 and 42 from the battery for backup.

In this embodiment, in a case that a criminal performs some act for illegally acquiring data and causes to occur a disconnection or a short circuit of the destruction detection patterns 31 and 41 and, when the disconnection or the short circuit of the destruction detection patterns 31 and 41 are detected by the destruction detection circuit, a predetermined processing such that data stored in the printed circuit boards 7 and 8 are erased or that the printed circuit boards 7 and 8 are set in a disabled state is executed to prevent illegal acquisition of data from the printed circuit boards 7 and 8.

(Principal Effects in this Embodiment)

As described above, in this embodiment, the conductor patterns 32 structuring the destruction detection pattern 31 are structured as described above and thus the conductor patterns 32 themselves can be arranged in a combined relationship of projections and recesses in a region where the pattern part groups 37 are combined. Similarly, in this embodiment, the conductor patterns 42 structuring the destruction detection pattern 41 are structured as described above and thus the conductor patterns 42 themselves can be arranged in a combined relationship of projections and recesses in a region where the pattern part groups 47 are combined.

Therefore, according to this embodiment, even when a space between the conductor patterns 32 and a space between the conductor patterns 42 are set to be relatively wide, in a case that the printed circuit board 7 and the FPC 25 are cut by a cutter or the like, the destruction detection patterns 32 and 42 are easily cut and, in a case that some illegal work is performed on the printed circuit board 7 and the FPC 25, the destruction detection patterns 32 and 42 are easily short-circuited. As a result, in this embodiment, even when a space between the conductor patterns 32 and a space between the conductor patterns 42 are set to be relatively wide, a security property of the card reader 1 to which the printed circuit board 7 and the FPC 25 are attached is secured. Therefore, according to this embodiment, while securing a security property of the card reader 1, cost of the printed circuit board 7 and the FPC 25 can be reduced and the destruction detection patterns 31 and 41 can be formed easily.

In this embodiment, parts of the destruction detection patterns 31 and 41 are structured by combining the pattern part groups 37 and 47. Therefore, according to this embodiment, even when the printed circuit board 7 and the FPC 25 are formed in a complicated shape other than a square shape or a rectangular shape or, even when a hole is formed in the printed circuit board 7 and the FPC 25, the destruction detection patterns 31 and 41 can be formed easily.

In this embodiment, one end of the conductor pattern 32 of the printed circuit board 7 and one end of the conductor pattern 42 of the FPC 25 are serially-connected, and one of the other end of the conductor pattern 32 and the other end of the conductor pattern 42 is connected with the destruction detection circuit, and the other of the other end of the conductor pattern 32 and the other end of the conductor pattern 42 is grounded. Therefore, in this embodiment, even when the destruction detection pattern 31 is formed on the printed circuit board 7 and the destruction detection pattern 41 is formed on the FPC 25, a circuit structure of the card reader 1 can be simplified.

(Other Embodiments)

Although the present invention has been shown and described with reference to a specific embodiment, various changes and modifications will be apparent to those skilled in the art from the teachings herein.

In the embodiment described above, a part of the destruction detection pattern 31 is structured by combining a plurality of pattern part groups 37. However, all of the destruction detection pattern 31 may be structured by combining a plurality of the pattern part groups 37. Similarly, in the embodiment described above, a part of the destruction detection pattern 41 is structured by combining a plurality of pattern part groups 47 but all of the destruction detection pattern 41 may be structured by combining a plurality of the pattern part groups 47.

In the embodiment described above, disconnection and a short circuit of the destruction detection patterns 31 and 41 are detected by the destruction detection patterns 31 and 41 and the destruction detection circuit. However, the present invention is not limited to this embodiment. For example, only one of disconnection and a short circuit of the destruction detection patterns 31 and 41 may be detected by the destruction detection patterns 31 and 41 and the destruction detection circuit. Further, in the embodiment described above, one end of the conductor pattern 32 and one end of the conductor pattern 42 are serially-connected with each other, and the conductor pattern 32 and the conductor pattern 42 are serially-connected with respect to the destruction detection circuit. However, the conductor pattern 32 and the conductor pattern 42 may be connected with a destruction detection circuit in parallel.

In the embodiment described above, the destruction detection pattern 31 is formed on the printed circuit board 7 but no destruction detection pattern 31 may be formed on the printed circuit board 7. In this case, for example, a flexible printed circuit board in which a destruction detection pattern similar to the destruction detection pattern 31 is formed is stuck on an inner side face of the first case body 23 so as to cover the entire inner peripheral face of the first case body 23. Further, in the embodiment described above, the FPC 25 is stuck on the inner peripheral face of the second case body 24 but no FPC 25 is stuck on the inner peripheral face of the second case body 24. In this case, for example, a destruction detection pattern similar to the destruction detection pattern 41 is formed on the printed circuit board 8.

In the embodiment described above, the card reader 1 is a manual type card reader. However, the card reader 1 may be a card conveyance type card reader having a card conveying mechanism structured to convey a card 2 automatically. Further, in the embodiment described above, the printed circuit board 7 is attached to the card reader main body 3 of the card reader 1 but the printed circuit board 7 may be attached to an apparatus other than the card reader main body 3. Similarly, the FPC 25 may be attached to an apparatus other than the case body 4 of the card reader 1.

While the description above refers to particular embodiments of the present invention, it will be understood that many modifications may be made without departing from the spirit thereof. The accompanying claims are intended to cover such modifications as would fall within the true scope and spirit of the present invention.

The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

What is claimed is:

1. A destruction detection pattern for use on a printed circuit board formed in a plate shape or a film shape, the destruction detection pattern comprising:
a conductor wound in a spiral shape;
wherein a width of the conductor is constant,
wherein, within an imaginary square overlaying the destruction detection pattern, the imaginary square having a side length that is 12 times the width of the conductor, and wherein a first direction is parallel to a first side of the imaginary square and a second direction parallel to a second side of the imaginary square that is perpendicular to the first side, the destruction detection pattern comprises a first pattern part, a second pattern part, a third pattern part and a fourth pattern part;
wherein the first pattern part comprises a first straight part which is formed in a straight shape and parallel to the first direction,
the second pattern part comprises:
a second straight part which is formed in a straight shape and parallel to the first direction and is shorter than the first straight part;
two third straight parts whose base ends are connected with both ends of the second straight part and which are formed in a straight shape and parallel to the second direction; and
two fourth straight parts which are formed in a straight shape and are extended from respective tip ends of the two third straight parts in the first direction;
the third pattern part comprises:
a fifth straight part which is formed in a straight shape and parallel to the first direction and is shorter than the second straight part;
two sixth straight parts whose base ends are connected with both ends of the fifth straight part and which are formed in a straight shape and parallel to the second direction; and
two seventh straight parts which are formed in a straight shape and are extended from respective tip ends of the two sixth straight parts in the first direction; and
the fourth pattern part comprises:
an eighth straight part which is formed in a straight shape and parallel to the first direction and is shorter than the fifth straight part;
two ninth straight parts whose base ends are connected with both ends of the eighth straight part and which are formed in a straight shape and parallel to the second direction; and
two tenth straight parts which are formed in a straight shape and are extended from respective tip ends of the two ninth straight parts in the first direction;
wherein the first pattern part, the second pattern part, the third pattern part and the fourth pattern part are arranged in sequential order in the second direction such that a center of the first straight part in the first direction, a center of the second straight part in the first direction, a center of the fifth straight part in the first direction, and a center of the eighth straight part in the first direction are coincided with each other in the first direction,
wherein a space between the first straight part and the second straight part in the second direction, a space between the second straight part and the fifth straight part in the second direction, a space between the fifth straight part and the eighth straight part in the second direction and the width of the conductor are equal to each other,
wherein a length of the third straight part, a length of the sixth straight part and a length of the ninth straight part are equal to each other,
wherein the second straight part is shorter than the first straight part by a same distance as the width of the conductor pattern, the fifth straight part is shorter than the second straight part by a same distance as 4 times of the width of the conductor pattern, and the eighth straight part is shorter than the fifth straight part by a same distance as 4 times of the width of the conductor pattern,
wherein a space in the first direction between the two ninth straight parts is equal to the width of the conductor pattern, and
wherein, in a second imaginary square identical to the first imaginary square and positioned adjacent to the first imaginary square, the first straight part of the first imaginary square is connected with a fourth straight part of the second imaginary square, one of the fourth straight parts of the first imaginary square is connected with a first straight part of the second imaginary square; and wherein the destruction detection pattern is structured to detect its own disconnection or its own short circuit.

2. A destruction detection pattern for use on a printed circuit board formed in a plate shape or a film shape, the destruction detection pattern comprising:
a conductor wound in a spiral shape
wherein a width of the conductor is constant,
wherein, within an imaginary square overlaying the destruction detection pattern, the imaginary square having a side length that is 12 times the width of the conductor, and wherein a first direction is parallel to a first side of the imaginary square and a second direction parallel to a second side of the imaginary square that is perpendicular to the first side, the destruction detection pattern comprises a first pattern part, a second pattern part, a third pattern part and a fourth pattern part;
wherein the first pattern part comprises a first straight part which is formed in a straight shape and parallel to the first direction,
the second pattern part comprises:
a second straight part which is formed in a straight shape and parallel to the first direction and is shorter than the first straight part;
two third straight parts whose base ends are connected with both ends of the second straight part and which are formed in a substantially straight shape and substantially parallel to the second direction; and
two fourth straight parts which are formed in a substantially straight shape and are extended from respective tip ends of the two third straight parts in the first direction;
the third pattern part comprises:
a fifth straight part which is formed in a straight shape and parallel to the first direction and is shorter than the second straight part;
two sixth straight parts whose base ends are connected with both ends of the fifth straight part and which are formed in a substantially straight shape and substantially parallel to the second direction; and
two seventh straight parts which are formed in a straight shape and are extended from respective tip ends of the two sixth straight parts in the first direction; and
the fourth pattern part comprises:
an eighth straight part which is formed in a substantially straight shape and substantially parallel to the first direction and is shorter than the fifth straight part;
two ninth straight parts whose base ends are connected with both ends of the eighth straight part and which are formed in a substantially straight shape and substantially parallel to the second direction; and
two tenth straight parts which are formed in a straight shape and are extended from respective tip ends of the two ninth straight parts in the first direction;
wherein the first pattern part, the second pattern part, the third pattern part and the fourth pattern part are arranged in sequential order in the second direction so that a center of the first straight part in the first direction, a center of the second straight part in the first direction, a center of the fifth straight part in the first direction, and a center of the eighth straight part in the first direction are coincided with each other in the first direction,
wherein a space between the first straight part and the second straight part in the second direction, a space between the second straight part and the fifth straight part in the second direction, a space between the fifth straight part and the eighth straight part in the second direction and the width of the conductor pattern are equal to each other,
wherein a length of the third straight part, a length of the sixth straight part and a length of the ninth straight part are equal to each other,
wherein the second straight part is shorter than the first straight part by a substantially same distance as the width of the conductor pattern, the fifth straight part is shorter than the second straight part by a substantially same distance as 4 times of the width of the conductor pattern, and the eighth straight part is shorter than the fifth straight part by a substantially same distance as 4 times of the width of the conductor pattern,
wherein a space in the first direction between the two ninth straight parts is substantially equal to the width of the conductor pattern, and
wherein, in a second imaginary square identical to the first imaginary square and positioned adjacent to the first imaginary square, the first straight part of the first imaginary square is connected with a fourth straight part of the second imaginary square, one of the fourth straight parts of the first imaginary square is connected with a first straight part of the second imaginary square; and wherein the destruction detection pattern is structured to detect its own disconnection or its own short circuit.

3. A card reader comprising:
a rigid circuit board which is a printed circuit board formed in a plate shape,
a flexible printed circuit board which is a printed circuit board formed in a film shape,
a card reader main body to which the rigid circuit board is attached; and
a case body which covers the card reader main body;
wherein the rigid circuit board and the flexible printed circuit board each comprise the destruction detection pattern claimed in claim 1;
wherein the case body comprises a first case body and a second case body which are divided in a thickness direction of the rigid circuit board;
wherein the first case body covers the rigid circuit board; and
wherein the flexible printed circuit board is stuck on an inner side face of the second case body so as to cover the entire inner side face of the second case body.

4. The card reader according to claim 3, wherein
one end of the conductor of the rigid circuit board and one end of the conductor of the flexible printed circuit board are serially-connected with each other,
one of the other end of the conductor of the rigid circuit board and the other end of the conductor pattern of the flexible printed circuit board is connected with a destruction detection circuit, and
the other of the other end of the conductor pattern of the rigid circuit board and the other end of the conductor pattern of the flexible printed circuit board is grounded.

5. A card reader comprising:
a rigid circuit board which is a printed circuit board formed in a plate shape,
a flexible printed circuit board which is a printed circuit board formed in a film shape,
a card reader main body to which the rigid circuit board is attached; and
a case body which covers the card reader main body;
wherein the rigid circuit board and the flexible printed circuit board each comprise the destruction detection pattern claimed in claim 2;
wherein the case body comprises a first case body and a second case body which are divided in a thickness direction of the rigid circuit board;
wherein the first case body covers the rigid circuit board; and
wherein the flexible printed circuit board is stuck on an inner side face of the second case body so as to cover the entire inner side face of the second case body.

6. The card reader according to claim 5, wherein
one end of the conductor of the rigid circuit board and one end of the conductor of the flexible printed circuit board are serially-connected with each other,
one of the other end of the conductor of the rigid circuit board and the other end of the conductor pattern of the flexible printed circuit board is connected with a destruction detection circuit, and
the other of the other end of the conductor pattern of the rigid circuit board and the other end of the conductor pattern of the flexible printed circuit board is grounded.
